(19) United States
(12) Patent Application Publication
(10) Pub. No.: US 2025/0219001 A1
(43) Pub. Date: Jul. 3, 2025

(54) SEMICONDUCTOR PACKAGE AND METHOD FOR MAKING THE SAME

(71) Applicant: STATS ChipPAC Pte. Ltd., Singapore (SG)

(72) Inventors: JongTae KIM, Incheon (KR); HangChul CHOI, Gyeonggi-do (KR); NamJu CHO, Gyeonggi-do (KR)

(21) Appl. No.: 19/004,456

(22) Filed: Dec. 30, 2024

(30) Foreign Application Priority Data
Jan. 3, 2024 (CN) 202410005153.9

(51) Int. Cl. H01L 23/00; H01L 21/48; H01L 21/56; H01L 23/31; H01L 23/498; H01L 23/538; H01L 25/065; H10B 80/00

(52) U.S. Cl. CPC H01L 24/16; H01L 21/4853; H01L 21/56; H01L 23/3135; H01L 23/49816; H01L 23/5385; H01L 23/5386; H01L 24/81; H01L 25/0657; H01L 24/11; H01L 2224/1132; H01L 2224/16145; H01L 2224/16227; H01L 2224/16238; H01L 2224/81815; H01L 2225/06513; H01L 2225/06517; H01L 2225/06562; H01L 2924/1815; H10B 80/00

(57) ABSTRACT

A method for making a semiconductor device is provided. The method includes providing a package base; attaching a first interposer layer on the package base via solder bumps; attaching a first semiconductor die on the package base and adjacent to the first interposer layer; attaching a second interposer layer on the first interposer layer via solder bumps to form an interposer stack, wherein the first interposer layer and the second interposer layer define a step structure, wherein the step structure comprises two step surfaces extending from the first interposer layer and the second interposer layer on the side of the interposer stack, respectively; attaching a second semiconductor die on both of the first semiconductor die and the first interposer layer; and forming a first encapsulant layer on the package base to encapsulate the first interposer layer, the second interposer layer, the first semiconductor die, and the second semiconductor die.

### TECHNICAL FIELD

The present application generally relates to semiconductor technology, and more particularly, to a semiconductor package and a method for making a semiconductor package.

### BACKGROUND OF THE INVENTION

Semiconductor devices are commonly found in modern electronic products, which perform a wide range of functions, such as signal processing, high-speed computation, transmitting and receiving electromagnetic signals, controlling electronic devices, and creating visual images for video displays. With the continued improvement in electronic products, it is desired to integrate more and more semiconductor dice in a single package. For example, semiconductor dice may be stacked together with through silicon vias (TSVs). However, for some packages, structures passing through a semiconductor die, such as TSVs, may not be viable.

Therefore, there is a need for an improved packaging technology for semiconductor devices with multiple semiconductor dice.

### SUMMARY OF THE INVENTION

An objective of the present application is to provide a semiconductor package having multiple semiconductor dice with enhanced efficiency in manufacture and improved applicability.

According to an aspect of the present application, a method for making a semiconductor package is provided. The method comprises: providing a package base; attaching a first interposer layer on the package base via solder bumps; attaching a first semiconductor die on the package base and adjacent to the first interposer layer; attaching a second interposer layer on the first interposer layer via solder bumps to form an interposer stack, wherein the first interposer layer and the second interposer layer define a step structure on a side of the interposer stack adjacent to the first semiconductor die, wherein the step structure comprises two step surfaces extending from the first interposer layer and the second interposer layer on the side of the interposer stack, respectively; attaching a second semiconductor die on both of the first semiconductor die and the first interposer layer; and forming a first encapsulant layer on the package base to encapsulate the first interposer layer, the second interposer layer, the first semiconductor die, and the second semiconductor die.

According to another aspect of the present application, a method for making a semiconductor package is provided. The method comprises: providing a substrate and a plurality of semiconductor dice; forming an integrated interposer block comprising an interposer portion with a plurality of layers of connection structures and a dummy portion; removing the dummy portion from the integrated interposer block to form an integrated interposer stack with a step structure on a side of the integrated interposer stack, wherein the integrated interposer stack comprises a plurality of interposer layers each having one layer of the plurality of layers of connection structures and an exposed step surface at the step structure; attaching the integrated interposer stack on the substrate; attaching a semiconductor die on the substrate and adjacent to the integrated interposer stack; attaching at least two semiconductor dice onto the integrated interposer stack, wherein each of the at least two semiconductor dice is attached partially on one of the exposed step surfaces; and forming an encapsulant layer on the substrate to encapsulate the integrated interposer stack and the semiconductor dice.

According to a further aspect of the present application, a method for making a semiconductor package is provided. The method comprises: providing a plurality of semiconductor dice; forming an integrated interposer block comprising a substrate, an interposer portion with a plurality of layers of connection structures and a dummy portion; removing the dummy portion from the integrated interposer block to form an integrated interposer stack integrated with the substrate, wherein the integrated interposer stack comprises a step structure on a side of the integrated interposer stack, wherein the integrated interposer stack comprises a plurality of interposer layers each having one layer of the plurality of layers of connection structures and an exposed step surface at the step structure; attaching a semiconductor die on the substrate and adjacent to the integrated interposer stack; attaching at least two semiconductor dice onto the integrated interposer stack, wherein each of the at least two semiconductor dice is attached partially on one of exposed step surfaces; and forming an encapsulant layer on the substrate to encapsulate the integrated interposer stack and the semiconductor dice.

According to yet a further aspect of the present application, a semiconductor package is provided. The semiconductor package comprises: a substrate; an interposer stack formed on the substrate, wherein the interposer stack comprises a plurality of interposer layers that are stacked together and define a step structure on a side of the interposer stack, and wherein the step structure comprises at least two step surfaces exposed from respective interposer layers of the interposer stack; a plurality of semiconductor dice stacked together on the substrate and adjacent to the step structure of the interposer stack, wherein each semiconductor die of the plurality of semiconductor dice is attached partially on the substrate, or on one of the step surfaces of the step structure; and an encapsulant layer formed on the substrate, wherein the encapsulant layer encapsulates the interposer stack and the plurality of semiconductor dice.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a semiconductor package according to an embodiment of the present application.

FIGS. 2A to 2G illustrate steps of a method for making a semiconductor package of FIG. 1 according to an embodiment of the present application.

FIGS. 3A to 3F illustrate steps of a method for making a semiconductor package of FIG. 1 according to another embodiment of the present application.

FIGS. 4A to 4C illustrate different methods for attaching an upper semiconductor die of a semiconductor package of FIG. 1 according to some embodiments of the present application.

FIG. 5 illustrates a semiconductor package according to another embodiment of the present application.

FIG. 6 illustrates a semiconductor package according to another embodiment of the present application.

FIGS. 7A to 7F illustrate steps for making a semiconductor package of FIG. 5 according to an embodiment of the present application.

FIGS. 8A to 8E illustrate steps for making a semiconductor package of FIG. 6 according to an embodiment of the present application.

The same reference numbers will be used throughout the drawings to refer to the same

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

In order to efficiently use space in a semiconductor package, multiple semiconductor dice may be stacked vertically in the package. Conventionally, electrical connections passing through a semiconductor die, such as TSV, may be formed through one or more semiconductor dice for electrically connecting the semiconductor dice at different heights. However, there are cases where such structures are not viable. The present application discloses a semiconductor package that is more universally applicable. The present semiconductor package has multiple semiconductor dice stacked together via various interposer layers.

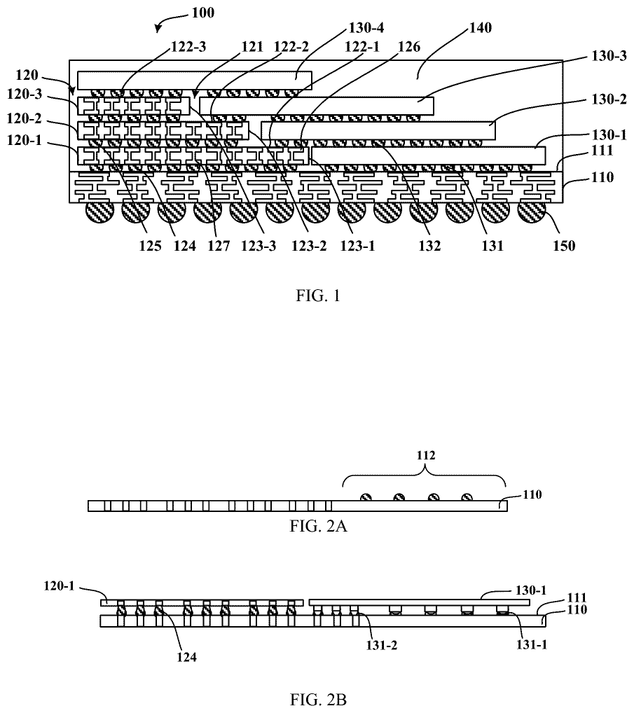

FIG. 1 illustrates a semiconductor package 100 according to an embodiment of the present application. The semiconductor package 100 includes a substrate 110, and an interposer stack 120, a plurality of semiconductor dice 130-1, 130-2, 130-3 and 130-4 and an encapsulant layer 140 formed on the substrate 110. Specifically, the interposer stack 120 and the plurality of semiconductor dice 130-1 to 130-4 are formed adjacent to each other on a top surface 111 of the substrate 110. The interposer stack 120 provides a stairstep structure for supporting the respective semiconductor dice 130-1 to 130-4 at different heights with respect to the substrate 110, while maintaining their electrical connection to the substrate 110, and preferably further between these semiconductor dice 130-1 to 130-4. The encapsulant layer 140 which is also formed on the top surface 111 encapsulates the interposer stack 120 and the semiconductor dice 130-1 to 130-4 for purpose of protections and electrical isolation.

The substrate 110 may include one or more insulating or passivation layers and one or more substrate interconnection structures formed in the insulating or passivation layers. Each substrate interconnection structure may include one or more conductive vias formed through the insulating or passivation layers, and one or more conductive layers formed on a top surface and/or a bottom surface of the substrate 110. The substrate 110 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The substrate 110 can also be a multi-layer flexible laminate, ceramic, copper clad laminate, or glass. In some embodiments, the substrate interconnection structures or redistribution layers (RDL) inside the substrate 110 can be formed using sputtering, electrolytic plating, electroless plating, or other suitable deposition process. The conductive vias and layers may be one or more layers of Al, Cu, Sn, Ni, Au, Ag, titanium (Ti), tungsten (W), or other suitable electrically conductive material.

Still referring to FIG. 1, the interposer stack 120 is formed on the top surface 111 of the substrate 110. Preferably, the interposer stack 120 is attached on the substrate 110 via solder bumps 124. The interposer stack 120 includes a plurality of interposer layers 120-1, 120-2 and 120-3 which are stacked together, preferably via solder bumps 125. It can also be understood that, in other embodiments, the plurality of interposer layers may be connected together using other means, such as by directly contacting the interposer layers. Each of the interposer layers 120-1, 120-2 and 120-3 may include conductive pathways, which may provide paths for power, ground, and data transmission to and from the electronic components attached thereon. For example, the interposer layer 120-1 may include conductive patterns 126 on its exposed surface for electrical connection to the semiconductor die, and the connection structures 127 extending and electrically passing through the interposer layer 120-1. The structure of the conductive patterns 126 and the connection structures 127 are not limited to the embodiments shown herein. For example, the material and structure of the interposer layers may be similar to the material and structure of the substrate 110, and will not be repeated herein.

Since the interposer stack 120 has different interposer layers that can be formed with the interposer stack 120, these different interposer layers may have different compositions, as well as the solder bumps therebetween, to meet different requirements of the semiconductor dice they are connecting. For example, if two semiconductor dice need to exchange a bigger current, for purpose of power supply, wider connection structures may be used for the interposer layer connecting the two semiconductor dice. For another example, if heavy data communication is desired between two semiconductor dice, denser connection structures may be used for the interposer layer connecting the two semiconductor dice, to provide more signal paths. Therefore, in some embodiments, the connection structures of the interposer layers in the interposer stack are not desired to be aligned with each other vertically.

As shown in FIG. 1, the plurality of interposer layers 120-1 to 120-3 may together define a step structure 121 on a side of the interposer stack 120. In general, the step structure 121 has a cross-section of steps of a staircase. The step structure 121 may include at least two step surfaces. For example, as shown in FIG. 1, the step structure 121 may have three step surfaces 122-1, 122-2 and 122-3 exposed from the interposer layers 120-1, 120-2 and 120-3, respectively. The step surfaces 122-1, 122-2 and 122-3 include conductive patterns which are exposed for electrical connection to the semiconductor dice thereon, respectively, as desired.

Each interposer layer of the interposer stack 120 also includes a rise surface between its step surface and a lower (step) surface. Preferably, each interposer layer is formed as a cube or cuboid, and its rise surface is perpendicular to its step surface. For example, the interposer layer 120-1 includes a rise surface 123-1 perpendicular to the step surface 122-1, the interposer layer 120-2 includes a rise surface 123-2 perpendicular to the step surface 122-2, and the interposer layer 120-3 includes a rise surface 123-3 perpendicular to the step surface 122-3. It can be understood that, in other embodiments, a rise surface may take other shapes and forms, such as a slope. As illustrated below, the height of the interposer layer may be preferably the same as that of the semiconductor die at the same level as the interposer layer, so as to standardize the manufacturing process. Preferably, the interposer layers of a interposer stack may have the same height, and may be manufactured using the same process.

As shown in FIG. 1, the step structure 121 of the interposer stack 120 is on the right side of the interposer stack 120. On the left side of the interposer stack 120, the interposer layers define substantially a vertical surface which is preferably flat. In other words, the left edges of the interposer layers are substantially in the same vertical plane, with or without gaps formed between the interposer layers. It can be understood that, both sides of the interposer stack 120 may take other forms to accommodate electronic components in the semiconductor package 100.

Still referring to FIG. 1, the plurality of semiconductor dice 130-1 to 130-4 are also stacked together on the top surface 111 of the substrate 110 and adjacent to the step structure 121. Preferably, the semiconductor die 130-1 is at least partially attached on the substrate 110 via solder bumps 131, but preferably be fully attached on the substrate 110. The semiconductor die 130-2 is attached partially on the semiconductor die 130-1, and partially on the step surface 122-1 of the interposer layer 120-1. Similarly, the semiconductor die 130-3 is partially attached on the step surface 122-2 of the interposer layer 120-2, and the semiconductor die 130-4 is partially attached on the step surface 122-3 of the interposer layer 120-3. In some embodiments, an upper semiconductor die is attached on a lower semiconductor die via solder bumps. For example, the semiconductor die 130-2 is attached on the semiconductor die 130-1 via solder bumps 132. Depending on whether conductive patterns are formed on the two surfaces of the semiconductor dice and/or the interposer layers, electrical connection or paths may or may not be formed between the two components that are physically connected through the solder bumps. For example, for the semiconductor die 130-2, there is no conductive pattern formed on a portion of its bottom surface which is aligned with the top surface of the semiconductor die 130-1, and thus the solder bumps there may not electrically connect the semiconductor die 130-2 with the semiconductor die 130-1. However, there may be conductive patterns formed on the other portion of the bottom surface of the semiconductor die 130-2, which is aligned with the top surface of the interposer layer 120-1, and thus the solder bumps there may electrically connect the semiconductor die 130-2 with the interposer layer 120-1.

As described above, in the semiconductor package 100, the semiconductor dice 130-1 to 130-4 may achieve electrical connection with each other and to the substrate 110 via the interposer stack 120. As such, the plurality of semiconductor dice 130-1 to 130-4 do not necessarily require wire bonds or TSVs therebetween. Therefore, the manufacturing process of the semiconductor package 100 can be simplified.

In order to realize a more stable structure, heights of the interposer layer and the semiconductor die of the semiconductor package 100 at the same level may be similar or the same as each other. For example, the heights of the interposer layer 120-1 and the semiconductor die 130-1 may be similar, and the heights of the interposer layer 120-2 and the semiconductor die 130-2 may be similar, etc. It can be understood that solder bumps used for attaching the interposer layers and the semiconductor dice may also have the same or similar height and/or similar material. In this case, the manufacturing process can be standardized and simplified. Also, during a bonding process such as a reflow process, the solder bumps of the interposer stack and the plurality of semiconductor dice may undergo a similar change, and height difference between the interposer layer and the semiconductor die at the same level after the bonding process may be minimized, and even avoided.

Still referring to FIG. 1, the semiconductor package 100 also includes the encapsulant layer 140 formed on the substrate 110 and thus on the interposer stack 110 and the semiconductor dice. In some embodiments, the encapsulant layer 140 can be a polymer composite material, such as epoxy resin, epoxy acrylate, or any suitable polymer with or without filler. The encapsulant layer 140 may be non-conductive, provide structural support, and environmentally protect the electronic devices from external environment and contaminants. The encapsulant layer 140 may be formed with any shape as desired. The encapsulant layer 140 may be formed by depositing an encapsulant or molding compound on the substrate 110 using injection molding, compressive molding, transfer molding, liquid encapsulant molding, vacuum lamination, spin coating, or another suitable processes.

In some embodiments, solder bumps 150 are mounted to a bottom surface of the substrate 110 for electrically connecting the semiconductor package 100 to external devices.

It can be understood that, in other cases, the interposer stack 120, the plurality of semiconductor dice 130-1 to 130-4, and the encapsulant layer 140 can be formed on various forms of bases. The semiconductor package 100 shown in FIG. 1 is formed on the substrate 110 which serves as the package base. In other embodiments, a substrate having at least one electronic component mounted thereon can also serve as the package base, and the at least one electronic component may together define a flat surface for further accommodating and supporting components thereon. For example, the package base may be a substrate mounted with a relatively large semiconductor die thereon, or a substrate already mounted with multiple interposer layers and a stack of semiconductor dice. That is to say, there may be other components between the interposer stack and the plurality of semiconductor dice and the substrate. For simplicity, the embodiments below use a substrate as a package base. Forms of the package base are not limited thereto.

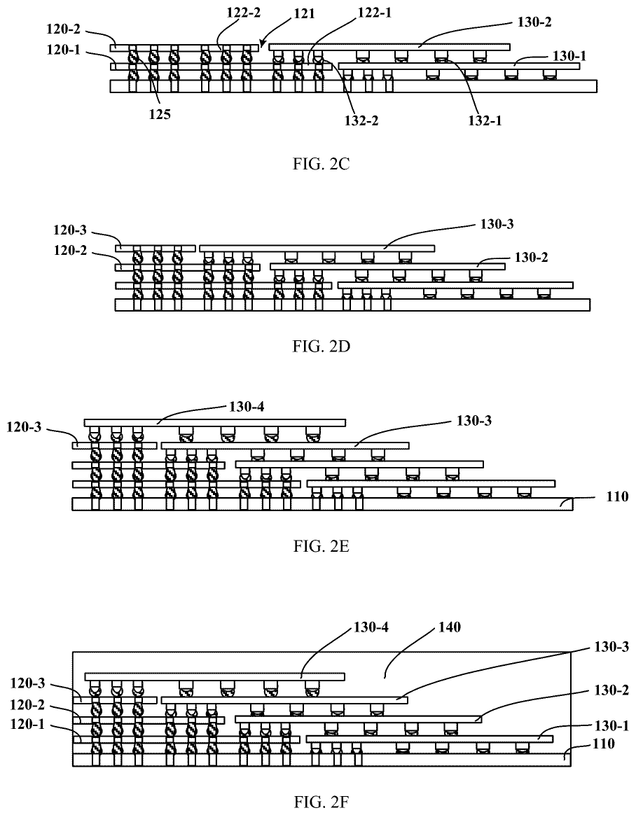

FIGS. 2A to 2G illustrate steps of a method for making the semiconductor package 100 of FIG. 1 according to an embodiment of the present application. For simplicity, connection structures of a substrate and interposer layers are shown as blocks. It can be understood that the form of the connection structures in a substrate or an interposer layer and the form of the conductive patterns on a substrate or an interposer layer are not limited thereto.

Referring to FIG. 2A, a substrate 110 is provided as a package base for accommodating electronic components thereon. In some embodiments, the substrate 110 may include a printing 112 area for printing epoxy solder paste thereon, and the epoxy solder paste may further attach to dummy bumps of a semiconductor die thereon. In some embodiments, pads may be formed on the printing area 112 of the substrate 110. Dummy bumps of a semiconductor die may be connected to the pads to further secure the mechanical interconnection.

Referring to FIG. 2B, an interposer layer 120-1 and a semiconductor die 130-1 are attached on a top surface 111 of the substrate 110. The semiconductor die 130-1 is adjacent to the interposer layer 120-1. In some embodiments, the interposer layer 120-1 is attached on the substrate 110 via solder bumps 124. The semiconductor die 130-1 may include dummy bumps 131-1 for attachment to the printing area 112 on the substrate 110. The dummy bumps 131-1 may be not electrically connected to the substrate 110, and only provide mechanical support for the components thereon. For example, conductive patterns that are connected to the dummy bumps 131-1 may not be electrically connected to the connection structures in the substrate 110, or there may be no conductive patterns under the dummy bumps 131-1. Other than that, the dummy bumps 131-1 may be the same as or similar to solder bumps which serve electrical connection purpose in material and shape. The semiconductor die 130-1 may also include solder bumps 131-2 which are electrically connected to the substrate 110 underneath. In some embodiments, the semiconductor die 130-1 may be a control circuit die, such as a memory device. In some embodiments, all of the bumps of the semiconductor die 130-1 are electrically connected to the substrate 110. Similar as the above embodiments, the substrate 110 may also include pads for attaching the semiconductor die 130-1. Preferably, the interposer layer 120-1 and the semiconductor die 130-1 may be of the same height, and the solder bumps 124 underneath the interposer layer 120-1 and the solder bumps 131-2 and dummy bumps 131-1 underneath the semiconductor die 130-1 may be of the same height and of the same material. Therefore, during a reflow process, the bumps of the interposer layer 120-1 and the semiconductor die 130-1 may undergo the same or similar change in height. Preferably, after an interposer layer and a semiconductor die at the same level are disposed on a lower base or layer, a bonding process can be performed to bond the interposer layer and the semiconductor die with the lower base or layer. In this way, the interposer layer and the semiconductor die supported on the lower base or layer has a better stability and thus can serve as a base for further attachment of additional layers of components and structures thereon. It can be understood that multiple levels of interposer layers and semiconductor dice can be firstly stacked together, and then a bonding process can be performed for the multiple levels. Preferably, for the interposer layer and the semiconductor die at a bottom level, they may be attached to the substrate via laser assisted bonding, and for the other levels of interposer layers and semiconductor dice which are relatively upper to the bottom level, they can be attached together using a reflow process for solder bumps or similar structures that are formed between the upper levels. It can be understood that all the levels of interposer layers and semiconductor dice may alternatively be attached together using a laser assisted bonding process.

Referring to FIG. 2C, an upper interposer layer 120-2 is attached on the relatively lower interposer layer 120-1 via solder bumps 125, and the two interposer layers 120-1 and 120-2 together form an interposer stack. The two interposer layers 120-1 and 120-2 together define a step structure 121 on a right side of the interposer stack adjacent to the first semiconductor die 130-1. The step structure 121 includes two step surfaces 122-1 and 122-2 extending from the first interposer layer 120-1 and the second interposer layer 120-2 on the right side, respectively. As illustrated below, more interposer layers can be stacked above the substrate 110.

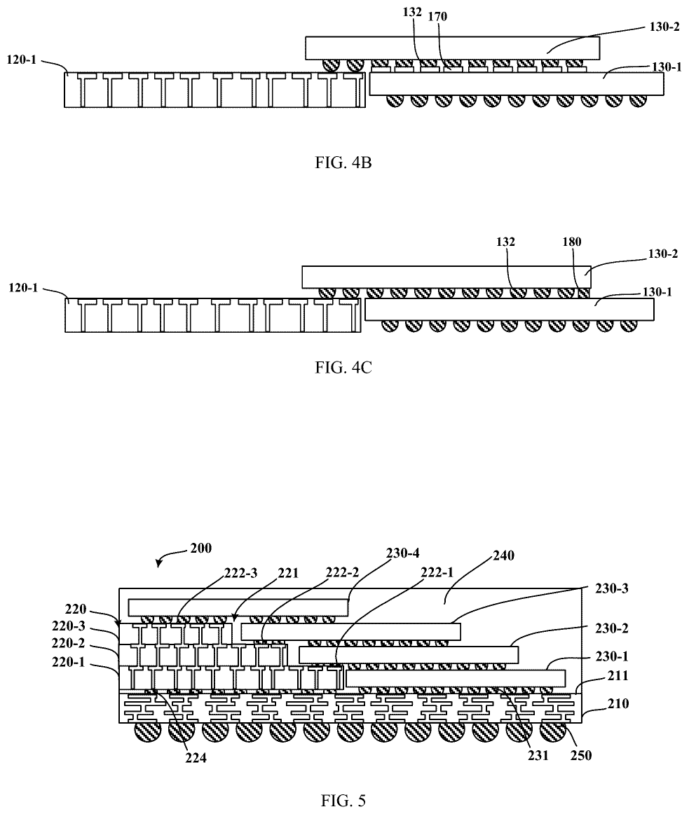

Still referring to FIG. 2C, an upper semiconductor die 130-2 is attached on both the relatively lower semiconductor die 130-1 and the relatively lower interposer layer 120-1, preferably via solder bumps. As can be seen, solder bumps 132-1 attached to the semiconductor die 130-2 may be dummy bumps 132-1 which only provide mechanical support to the semiconductor die 130-2. In some embodiments, epoxy is applied on the solder bumps 132-1 using a dipping process to assist adhesion between the solder bumps 132-1 and the semiconductor die 130-1 attached beneath. Solder bumps 132-2 of the semiconductor die 130-2 may be attached to conductive patterns which are exposed on the interposer layer 120-1 to achieve electrical connection with the interposer layer 120-1, with the substrate 110, and optionally with other electronic components such as the semiconductor die 130-1. Similar as that illustrated in FIG. 2B, preferably, the height of the interposer layer 120-2 is similar or the same as the semiconductor die 130-2. In some other embodiments, the attachment of an upper semiconductor die on a lower semiconductor die may include other techniques such as that illustrated with FIGS. 4A to 4C.

Referring to FIG. 2D, similar to FIG. 2C, another upper interposer layer 120-3 is attached on the relatively lower interposer layer 120-2 via solder bumps, and another upper semiconductor die 130-3 is attached both on the relatively lower semiconductor die 130-2 and the relatively lower interposer layer 120-2, preferably via solder bumps. As shown in FIG. 2D, the interposer layer 120-3 may constitute a part of the interposer stack. Preferably, in the interposer stack, the interposer layers have a decreasing length or width from bottom to top. In this way, the top surfaces of the interposer layers may be at least partially exposed, and thus can be used for attachment of components thereon.

Referring to FIG. 2E, the interposer stack includes three interposer layers, and the interposer layer 120-3 which is farthest from the substrate 110 defines a top interposer layer. A semiconductor die 130-4 is attached both on the top interposer layer 120-3 and the semiconductor die 130-3. It can be understood that, in some embodiments, other electronic components may be attached on the interposer layer 120-3 and the semiconductor die 130-3. For example, a further layer of interposer layer and semiconductor die may be attached.

Referring to FIG. 2F, an encapsulant layer 140 is formed on the substrate 110 to encapsulate the interposer layers 120-1 to 120-3 and the semiconductor dice 130-1 to 130-4. The encapsulant layer 140 may be formed by depositing an encapsulant or molding compound on the substrate 110 using injection molding, compressive molding, transfer molding, liquid encapsulant molding, vacuum lamination, spin coating, or another suitable processes.

Referring to FIG. 2G, solder bumps 150 may be mounted on a bottom surface of the substrate 110. Therefore, the electronic components on the substrate 110 may achieve electrical connection with external devices through the solder bumps 150.

The method shown in FIGS. 2A to 2G simplifies the molding process for multiple layers. However, for stability of the overall stack having multiple layers, the molding process can be performed for several times, rather than once. For example, firstly, a first encapsulant layer can be formed for several layers of interposer layers and semiconductor dice stacked on the substrate. After this, further interposer layer(s) and semiconductor die or dice can be stacked thereon, and a second encapsulant layer can be formed on the first encapsulant layer, so on and so forth.

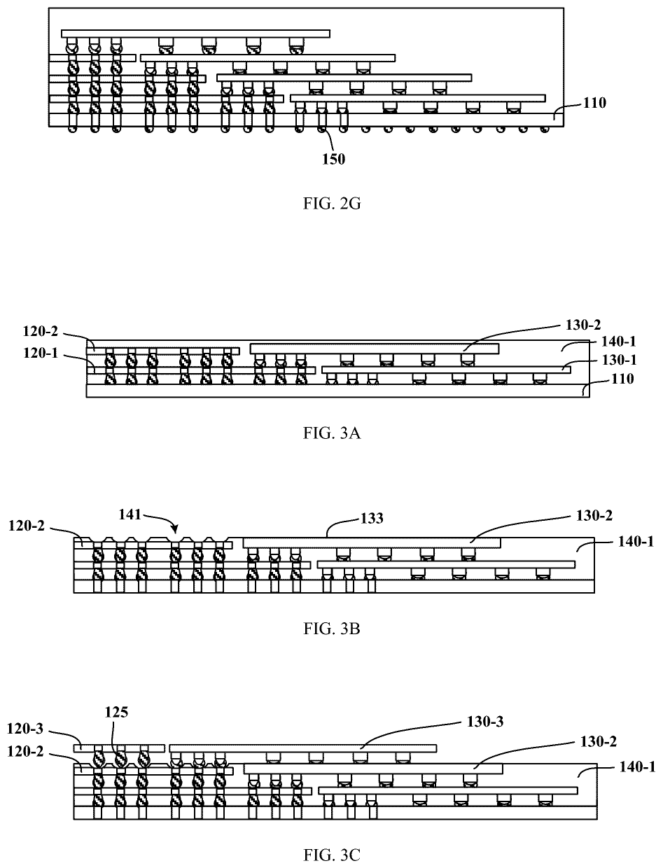

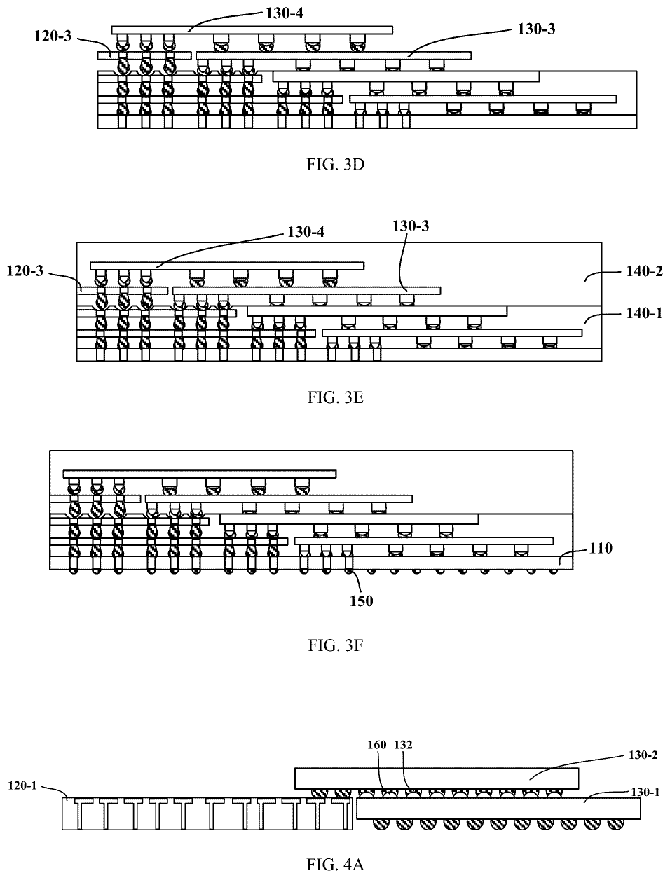

FIGS. 3A to 3F illustrate steps of a method for forming an encapsulant layer for multiple times according to an embodiment of the present application. When the encapsulant layer is formed for multiple times, a stack of relatively large number of layers can be achieved. Also, in some cases, because of the defect of a component or height change in a bonding process, heights of the components may change. Especially for a relatively higher layer of interposer layer and semiconductor die, the error in height relative to a substrate may be accumulated, and the interposer layer and the semiconductor die cannot be well aligned at the same level. For these cases, forming the encapsulant layer for multiple times may help eliminate the accumulated height difference. Thus, for the interposer layer and the semiconductor die formed later on an encapsulant layer, they may be not affected by the accumulated height difference of the layers underneath. The steps for forming the encapsulant layer for multiple times are illustrated below.

Referring to FIG. 3A, an interposer layer 120-1 and a semiconductor die 130-1 adjacent to the interposer layer 120-1 are formed on the substrate. Furthermore, an interposer layer 120-2 and a semiconductor die 130-2 are formed thereon. The formation of the components may refer to the illustration of FIGS. 2A to 2C, and will not be repeated herein. Different from the method shown above, in FIG. 3A, a first encapsulant layer 140-1 is formed to encapsulate the interposer layers 120-1, 120-2 and the semiconductor dice 130-1, 130-2.

Referring to FIG. 3B, openings 141 are formed through the first encapsulant layer 140-1 to expose conductive patterns on a top surface of the interposer layer 120-2. In some embodiments, the encapsulant layer 140-1 may fully encapsulate the semiconductor die 130-2. That is, a top surface of the semiconductor die 130-2 is not exposed from the encapsulant layer 140-1. Preferably, as shown in FIG. 3B, the top surface 133 of the semiconductor die 130-2 may be exposed. Processes such as film assisted molding, grinding and/or plasma etching can be performed to remove an encapsulant material of the first encapsulant layer 140-1 above the semiconductor die 130-2 to expose a top surface 133 of the semiconductor die 130-2. Therefore, electronic components may be attached directly on the top surface 133 of the semiconductor die 130-2, which is advantageous for heat dissipation, because the semiconductor dice may be thermally connected together through dummy bumps. In some embodiments, a thermally conductive layer may be formed on the top surface 133 of the semiconductor die 130-2 or on the first encapsulant layer 140-1 above the semiconductor die 130-2, which can be thermally connected with but electrically isolated from the dummy bumps that will be formed later above the semiconductor die 130-2. The thermally conductive layer can be extended to a lateral surface (e.g., a right lateral surface) of the first encapsulant layer 140-1 to provide a heat dissipation path from the inside to the exterior of the semiconductor package. It can be appreciated that similar thermally conductive layers such as copper layers may be formed for other encapsulant layers or even other semiconductor dice. Preferably, laser ablation is used for forming the openings.

Referring to FIG. 3C, an interposer layer 120-3 and a semiconductor die 130-3 are attached on the first encapsulant layer 140-1. Specifically, the interposer layer 120-3 is attached to a part of the exposed conductive patterns on the top surface of the interposer layer 120-2 through solder bumps 125 to be electrically connected to the interposer layer 120-2.

Still referring to FIG. 3C, the semiconductor die 130-3 is attached both on the interposer layer 120-2 and the semiconductor die 130-2. Specifically, the semiconductor die 130-3 is attached on the encapsulant layer 140-1 through solder bumps to at least partially electrically connect the semiconductor die 130-3 with the exposed conductive patterns on the top surface of the interposer layer 120-2.

Referring to FIG. 3D, a semiconductor die 130-4 is attached on the interposer layer 120-3 and the semiconductor die 130-3.

Referring to FIG. 3E, a second encapsulant layer 140-2 is formed on the first encapsulant layer 140-1 to encapsulate the interposer layer 120-3, the semiconductor dice 130-3 and 130-4 on the first encapsulant layer 140-1. Referring to FIG. 3F, solder bumps 150 can be mounted on a bottom surface of the substrate 110.

FIGS. 2A to 2G and FIGS. 3A to 3F illustrate two methods for making a semiconductor package such as the semiconductor package 100 shown in FIG. 1. In the above methods for stacking semiconductor dice, when an upper semiconductor die is attached on a lower semiconductor die and a lower interposer layer, the attachment of the solder bumps of the upper semiconductor die may adopt one or more of the methods illustrated in FIGS. 4A to 4C. FIGS. 4A to 4C take the semiconductor die 130-2 which is formed on both the interposer layer 120-1 and the semiconductor die 130-1 shown in FIG. 1 as an example, but it can be understood that, the method illustrated herein may apply to other semiconductor dice.

Referring to FIG. 4A, for the semiconductor die 130-2 attached with the solder bumps 132, flux such as epoxy 160 is applied using a dipping process on the solder bumps 132, the solder bumps 132 are then attached to the semiconductor die 130-1 underneath. Preferably, the solder bumps 132 applied with epoxy 160 may be dummy bumps that only provide mechanical support on the semiconductor die 130-1. Such process is generally referred to as epoxy flux dipping.

Referring to FIG. 4B, at least one dummy pad 170 is formed on a top surface of the lower semiconductor die 130-1, and solder bumps 132 of the semiconductor die 130-2 may be attached on the dummy pads 170. In some embodiments, the dummy pads 170 may be formed by depositing and patterning a metal material such as copper, aluminum on the top surface of the semiconductor die 130-2. The dummy pads 170 may also be formed by sputtering, CVD, PVD, ink printing etc. The dummy pads 170 may have a thickness that is significantly smaller than the height of the dummy bumps 132, which may not affect the horizontal alignment between the semiconductor die 130-2 and an interposer layer which is to be formed at the same level as the semiconductor die 130-2.

Referring to FIG. 4C, pre-dot flux such as pre-dot epoxy 180 may be dispensed on the semiconductor die 130-1. Preferably, pre-dot epoxy 180 is dispensed at or close to the perimeter of solder bumps 132. The pre-dot epoxy 180 has a predetermined height to maintain standoff distance between the lower semiconductor die 130-1 and the upper semiconductor die 130-2 during bonding and prevent interconnect defects.

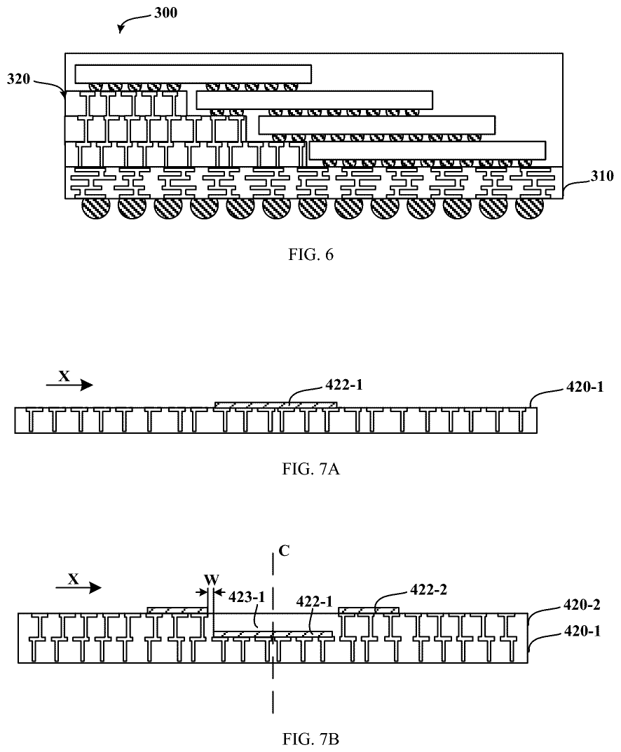

The semiconductor package of the present application such as the semiconductor 100 shown in FIG. 1 may have other variations, which will be illustrated with reference to FIG. 5 and FIG. 6. Specifically, as shown in FIG. 5, multiple interposer layers of the interposer stack may be integrally formed, or further, as shown in FIG. 6, the substrate may be integrally formed with the interposer stack.

Referring to FIG. 5, a semiconductor package 200 includes a substrate 210, an interposer stack 220 formed on the substrate 210, a plurality of semiconductor dice 230-1 to 230-4 stacked together on the substrate 210 and adjacent to the interposer stack 220. Similar as the above embodiments, the interposer stack 220 is mounted on the substrate 210 via solder bumps 224, and includes a plurality of interposer layers 220-1, 220-2 and 220-3. These interposer layers 220-1, 220-2 and 220-3 together define a step structure 221 on a side of the interposer stack 220. The interposer layers 220-1, 220-2 and 220-3 include step surfaces 222-1, 222-2 and 222-3 which are exposed from respective interposer layers for attaching with the respective semiconductor dice.

Still referring to FIG. 5, the plurality of semiconductor dice 230-1 to 230-4 are attached on the substrate 210 preferably via solder bumps 231. Each semiconductor die may be attached partially on the substrate 210, or on one of the step surfaces 222-1, 222-2 and 222-3 of the step structure 221. An encapsulant layer 240 is also formed on the substrate 210, which encapsulates the interposer stack 220 and the plurality of semiconductor dice 230-1 to 230-4. Preferably, the substrate 210 is mounted with solder bumps 250 for attaching the semiconductor package 200 with other electrical devices.

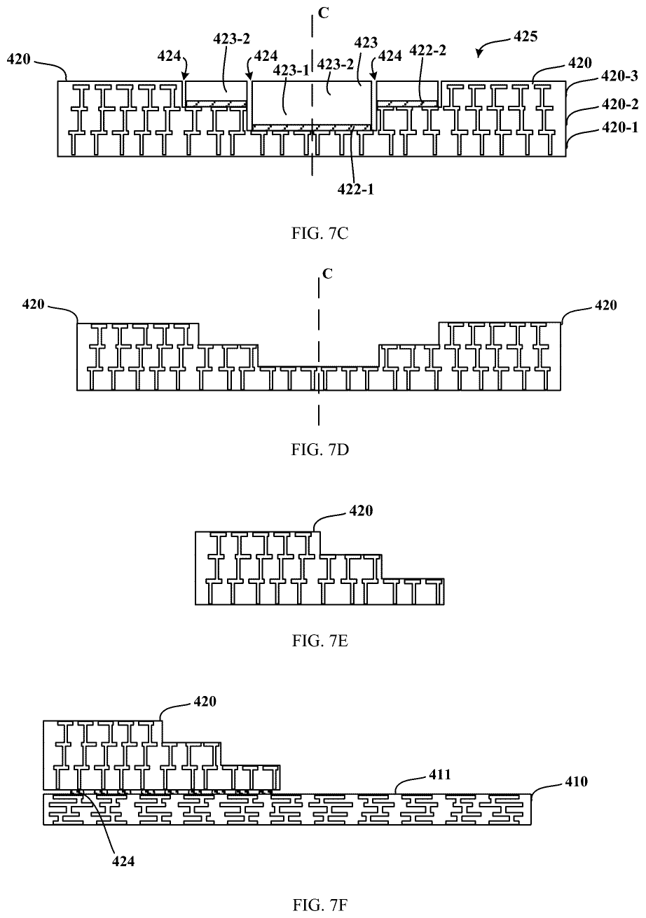

The semiconductor package 200 is different from the above semiconductor package 100 shown in FIG. 1 in that the interposer stack 220 is integrally formed together prior to being attached on the substrate 210. That is, instead of being attached with each other via additional solder bumps after or when they are attached individually on the substrate 210, interposer layers of the interposer stack 220 may be formed integrally as a single piece, and conductive pathways are formed inside and through the multiple interposer layers. The method for making the interposer stack 220 may refer to FIGS. 7A to 7F. For illustration purpose, interfaces between the layers are shown in FIG. 5 to distinguish different interposer layers.

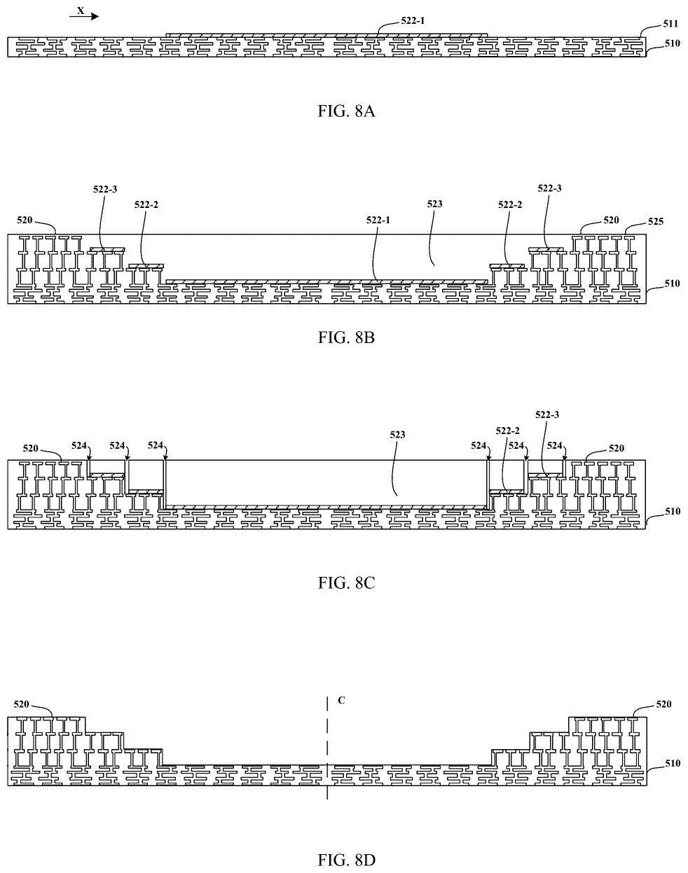

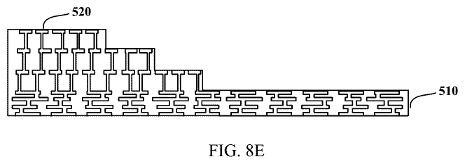

FIG. 6 shows a semiconductor package 300 according to another embodiment of the present application. As shown in FIG. 6, the semiconductor package 300 is generally similar as the semiconductor package 200 shown in FIG. 5. Different from the semiconductor package 200, in the semiconductor package 300, the interposer stack 320 and the substrate 310 are integrally formed together as a single piece. The method for forming the interposer stack 320 integrated with the substrate 310 may refer to FIGS. 8A to 8E.

FIGS. 7A to 7F illustrate steps for making a semiconductor package 200 with an integrated interposer stack shown in FIG. 5. It can be understood that the connection structures of the substrate and the interposer layers may take various forms and are not limited to the embodiments shown herein.

In order to form the semiconductor package 200, similar as the method for making the semiconductor package 100 as shown in FIGS. 2A to 2G, a substrate and a plurality of semiconductor dice can be provided. The integrated interposer stack may be formed by the steps illustrated below. Then, the integrated interposer stack and the semiconductor dice are attached on the substrate, and an encapsulant layer is formed on the substrate. Steps similar as the method for making the semiconductor package 100 as shown in FIGS. 2A to 2G may refer to the above embodiments.

The formation of the integrated interposer stack is shown in FIGS. 7A to 7E. Referring to FIG. 7A, an interposer portion 420-1 with a layer of connection structures is formed. A length of the interposer portion 420-1 may be two times of that of the interposer layer 220-1 shown in FIG. 5. The connection structures may include a set of die connection structures for further electrically coupling corresponding semiconductor dice on the step surfaces, and a set of interlayer connection structures extending through the layer of connection structures. After the interposer portion 420-1 is formed, a barrier layer 422-1 is formed on the interposer portion 420-1. The barrier layer 422-1 helps define a position where a step surface of the step structure of the interposer stack is formed. Preferably, for a bottom interposer portion 420-1, the barrier layer 422-1 is formed on a central position along the extending direction X of the interposer portion 420-1, so that the interposer portion 420-1 may allow manufacture of two interposer stacks symmetric to each other at a time.

Specifically, the barrier layer 422-1 may have a similar material and composition as a dummy layer. In some embodiments, the barrier layer 422-1 may include a release material, which may be any suitable material that allows separating the barrier layer 422-1 from the materials at both sides of the barrier layer 422-1 when sufficient force is applied. For example, the barrier layer 422-1 may be siloxanes (silicone-based polymers), or flaky materials (e.g., talc). The barrier layer 422-1 may be formed using any suitable technique such as screen printing. In some embodiments, the barrier layer 422-1 may be a metal layer, for example, a copper layer that serves as a laser drilling stop layer, it may absorb the thermal energy produced by the laser light.

Referring to FIG. 7B, an interposer portion 420-2 with a layer of connection structures inside is further formed on the interposer portion 420-1. Specifically, the connection structures of the interposer portion 420-2 are formed at a location on the interposer portion 420-1 except above the barrier layer 422-1, and a dummy portion 423-1 is formed on the barrier layer 422-1.

Similar as the process shown in FIG. 7A, in order to form the step structure, a barrier layer 422-2 is further formed on the interposer portion 420-2 at a location for the step surface of the step structure as shown in FIG. 5. As illustrated above, preferably, the method may form two integrated interposer stacks symmetric to each other at one time. Therefore, the layout of the components on the substrate during each step of the method may be a generally symmetric layout, i.e., a mirrored layout. Specifically, the barrier layer 422-2 is formed symmetrically with respect to a center line C of the overall structure along the extending direction X. The barrier layer 422-2 is formed outside of the barrier layer 422-1. Specifically, there remains a gap W between adjacent edges of the barrier layer 422-2 and the barrier layer 422-1 along the direction X. As will be illustrated below, the gap W is used for further forming openings and detaching dummy portions. At the bottom of the openings, a conner of a step surface will be formed. Along an inner surface of the openings, a rise surface perpendicular to a step surface will also be formed. It can be understood that, since openings are formed for the corner of a step surface, the barrier layers 422-1, 422-2 do not need to extend to the openings, i.e., conners of the lower step surfaces. As such, step surfaces except the top step surface may be formed with the respective barrier layers.

Referring to FIG. 7C, similar as the process shown in FIG. 7B, an interposer portion 420-3 is further formed on the interposer portion 420-2, a dummy portion 423-2 is further formed on the dummy portion 423-1 and on the barrier layer 422-2. The dummy portions 423-1 and 423-2 together constitute a dummy portion 423. Since no electronic connection is formed on a barrier layer, an area on the barrier layers 422-1, 422-2 defines the dummy portion 423. The interposer portions 420-1 to 420-3 together constitute two interposer stacks 420. The interposer stacks 420 and the dummy portion 423 together constitute an integrated interposer block 425. The integrated interposer block 425 is symmetric with relative to its central line C. Specifically, the two interposer stacks 420 are symmetric to each other with respect to the dummy portion 423 therebetween.

Further, a drilling process, such as laser drilling, is performed to form openings 424 at the locations of conners of the lower step surfaces, so as to expose the conners of the lower step surfaces. By forming the openings 424, rise surfaces of the step structure of the interposer stack may be formed. Also, the dummy portions 423-1, 423-2 can be easily removed since the side surfaces of the dummy portions are not in contact with the interposer stacks 420.

Referring to FIG. 7D, along the openings 424 and the barrier layers 422-1 and 422-2, the dummy portion 423 is removed. As illustrated above, the barrier layers 422-1 and 422-2 may use a release material that has chemical and physical properties that allow the dummy portion 423 to be removed from the barrier layers 422-1, 422-2 by exerting a mechanical force, without deforming the interposer stacks 420. The removal of the dummy portion 423 from the integrated interposer block 425 may be performed using any suitable techniques. For example, the dummy portion 423 and the interposer stacks 420 may be removed from each other using a vacuum device. The barrier layers 422-1 and 422-2 can also be removed using any suitable processes. Upon removing the barrier layers 422-1, 422-2 and the dummy portion 423, two interposer stacks that are symmetric to each other are remained, and conductive patterns of the die connection structures are exposed from the corresponding step surface. Singulation at the center line C is then performed to singulate the two interposer stacks 420 from each other, each piece being an interposer stack 420 as shown in FIG. 7E.

Referring to FIG. 7F, an interposer stack 420 is attached on a top surface 411 of the substrate 410 via solder bumps 424. After the interposer stack 420 is attached, a plurality of semiconductor dice can be sequentially stacked adjacent to the interposer stack 420 and an encapsulant layer can be formed on the substrate 410 to encapsulate the components thereon, similar as shown in FIGS. 2A to 2G, to obtain the semiconductor package 200 shown in FIG. 5. The attachment of the plurality of semiconductor dice may refer to the above embodiments and will not be repeated herein.

Different from the method shown in FIGS. 2A to 2G, since the interposer stack 420 is integrally formed as a single piece, the plurality of semiconductor dice can be attached together at one time, and an upper semiconductor die does not have to be attached after the bonding process for a lower semiconductor die. This helps to simplify the manufacturing process and enhance efficiency.

As shown above in FIG. 6, the interposer stack 320 and the substrate 310 may be integrally formed together. FIGS. 8A to 8E illustrate steps for making a semiconductor package with the interposer stack and the substrate integrally formed together. Steps similar as the method for making the semiconductor package 200 shown in FIGS. 7A to 7F may refer to the above embodiments.

Referring to FIG. 8A, a base substrate 510 is provided. The base substrate may have a length of two times of a substrate of the semiconductor package 300 shown in FIG. 6. A barrier layer 522-1 is formed on a top surface 511 of the base substrate 510. Preferably, the barrier layer 522-1 is at the center along the extending direction X of the base substrate 510.

Referring to FIG. 8B, similar as the process shown in FIGS. 7B and 7C, multiple interposer layers are stacked at two opposite sides of the base substrate 510 to form two integrated interposer stacks 520. Barrier layers 522-2 and 522-3 are formed at locations of the step surfaces, and a dummy portion 523 is formed on the barrier layers 522-1, 522-2 and 522-3 between the two integrated interposer stacks 520. Therefore, the base substrate 510, the two interposer stacks 520, and the dummy portion 523 constitute an integrated interposer block 525.

Referring to FIG. 8C, openings 524 are formed at edges of the barrier layers 522-1, 522-2 and 522-3 for removal of the dummy portion 523. Then the two integrated interposer stacks 520 integrated with the base substrate 510 underneath can be obtained as shown in FIG. 8D. A singulation process is performed at a center line C on the base substrate 510 to singulate the base substrate 510 and the components thereon into two pieces, each piece being an integrated interposer stack 520 integrated with half of the base substrate 510 as shown in FIG. 8E. Herein, each half of the base substrate 510 constitutes a substrate 510 integrated with the corresponding interposer stack 520.

After the formation of the integrated interposer stack 520 and the substrate 510, the plurality of semiconductor dice may be stacked thereon. Further steps for making the semiconductor package may refer to the above embodiments.

In the method for making the semiconductor packages 200, 300 respectively shown in FIGS. 5 and 6, since the interposer stacks are integrally formed as a single piece, heights for attaching the corresponding semiconductor dice are predetermined and may not change during a bonding process. The semiconductor dice may be first stacked together, and then undergo the bonding process for only one time, which may greatly reduce the number of bonding process and simplify the semiconductor die attaching process.

The discussion herein included numerous illustrative figures that showed various steps in a method of making several semiconductor packages. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making a semiconductor package, comprising:
providing a package base;
attaching a first interposer layer on the package base via solder bumps;
attaching a first semiconductor die on the package base and adjacent to the first interposer layer;
attaching a second interposer layer on the first interposer layer via solder bumps to form an interposer stack, wherein the first interposer layer and the second interposer layer define a step structure on a side of the interposer stack adjacent to the first semiconductor die, wherein the step structure comprises two step surfaces extending from the first interposer layer and the second interposer layer on the side of the interposer stack, respectively;
attaching a second semiconductor die on both of the first semiconductor die and the first interposer layer; and
forming a first encapsulant layer on the package base to encapsulate the first interposer layer, the second interposer layer, the first semiconductor die, and the second semiconductor die.

2. The method of claim 1, wherein providing a package base comprises:
providing a substrate as the package base; or
providing a substrate having at least one electronic component mounted thereon as the package base, wherein the at least one electronic component together define a flat surface.

3. The method of claim 1, wherein attaching a second semiconductor die on both of the first semiconductor die and on the first interposer layer comprises:
applying flux using a dipping process on the solder bumps which are attached to the second semiconductor die;
attaching dummy bumps of the second semiconductor die on dummy pads of the first semiconductor die; and/or
dispensing pre-dot flux on the first semiconductor die.

4. The method of claim 1, further comprising:
forming openings through the first encapsulant layer to expose conductive patterns on a top surface of the second interposer layer.

5. The method of claim 4, further comprising:
attaching a third semiconductor die on the first encapsulant layer through solder bumps to at least partially electrically connect the third semiconductor die with the exposed conductive patterns on the top surface of the second interposer layer.

6. The method of claim 5, further comprising:
forming a second encapsulant layer to encapsulate the first encapsulant layer and the third semiconductor die.

7. The method of claim 4, further comprising:
attaching a third interposer layer on the first encapsulant layer through solder bumps to electrically connect the third interposer layer with a part of the exposed conductive patterns on the top surface of the second interposer layer.

8. The method of claim 7, further comprising:
forming a second encapsulant layer to encapsulate the first encapsulant layer and the third interposer layer.

9. The method of claim 4, wherein before forming openings through the first encapsulant layer, the method further comprises:
removing an encapsulant material of the first encapsulant layer above the second semiconductor die to expose a top surface of the second semiconductor die.

10. A method for making a semiconductor package, comprising:
providing a substrate and a plurality of semiconductor dice;
forming an integrated interposer block comprising an interposer portion with a plurality of layers of connection structures and a dummy portion;
removing the dummy portion from the integrated interposer block to form an integrated interposer stack with a step structure on a side of the integrated interposer stack, wherein the integrated interposer stack comprises a plurality of interposer layers each having one layer of the plurality of layers of connection structures and an exposed step surface at the step structure;
attaching the integrated interposer stack on the substrate;
attaching a semiconductor die on the substrate and adjacent to the integrated interposer stack;
attaching at least two semiconductor dice onto the integrated interposer stack, wherein each of the at least two semiconductor dice is attached partially on one of the exposed step surfaces; and
forming an encapsulant layer on the substrate to encapsulate the integrated interposer stack and the semiconductor dice.

11. The method of claim 10, wherein forming an integrated interposer block comprises:
forming the integrated interposer block comprising two interposer portions and a dummy portion between the two interposer portions, wherein the two interposer portions are symmetric to each other with relative to the dummy portion; and
wherein removing the dummy portion from the integrated interposer block to form an integrated interposer stack with a step structure on a side of the integrated interposer stack comprises:
removing the dummy portion from the integrated interposer block; and
singulating the two interposer portions into two pieces to obtain the integrated interposer stack with the step structure.

12. The method of claim 10, wherein forming an integrated interposer block comprises:
forming a plurality of layers of connection structures, wherein each layer of connection structures comprises a set of die connection structures and a set of interlayer connection structures extending through the layer;
forming barrier layers on lower layers of connection structures at a position of lower step surfaces, wherein conners of the lower step surfaces are not formed with the barrier layers, and wherein an area on the barrier layers defines the dummy portion of the integrated interposer block;
performing laser drilling at the conners of the lower step surfaces to expose the conners of the lower step surfaces;
removing the barrier layers and the dummy portion from the integrated interposer block; and wherein
upon removing the dummy portion from the integrated interposer block, conductive patterns of the set of die connection structures are exposed from the corresponding step surface at an interposer layer for electrically coupling a corresponding semiconductor die on the step surface.

13. The method of claim 10, wherein removing the dummy portion from the integrated interposer block comprises laser drilling the dummy portion.

14. The method of claim 10, wherein attaching at least two semiconductor dice onto the integrated interposer stack comprises:
applying flux using a dipping process on solder bumps which are attached to one of the at least two semiconductor dice;
attaching dummy bumps of one of the at least two semiconductor dice on dummy pads of a semiconductor die under the one semiconductor die; and/or
dispensing pre-dot flux on one of the at least two semiconductor dice and the semiconductor die attached on the substrate.

15. A semiconductor package, comprising:
a substrate;
an interposer stack formed on the substrate, wherein the interposer stack comprises a plurality of interposer layers that are stacked together and define a step structure on a side of the interposer stack, and wherein the step structure comprises at least two step surfaces exposed from respective interposer layers of the interposer stack;
a plurality of semiconductor dice stacked together on the substrate and adjacent to the step structure of the interposer stack, wherein each semiconductor die of the plurality of semiconductor dice is attached partially on the substrate, or on one of the step surfaces of the step structure; and
an encapsulant layer formed on the substrate, wherein the encapsulant layer encapsulates the interposer stack and the plurality of semiconductor dice.

16. The semiconductor package of claim 15, wherein the interposer stack is integrally formed together and mounted on the substrate via solder bumps.

17. The semiconductor package of claim 15, wherein the interposer stack and the substrate are integrally formed together.

18. The semiconductor package of claim 15, wherein the plurality of interposer layers of the interposer stack are stacked on top of each other via solder bumps.

19. The semiconductor package of claim 15, wherein a lower semiconductor die of the plurality of semiconductor dice comprises at least one dummy pad on a top surface of the lower semiconductor die.
